(19) United States
(12) Patent Application Publication
(10) Pub. No.: US 2023/0059733 A1
(43) Pub. Date: Feb. 23, 2023

(54) METHOD FOR MANUFACTURING SEMICONDUCTOR STRUCTURE AND SEMICONDUCTOR STRUCTURE

(71) Applicant: CHANGXIN MEMORY TECHNOLOGIES, INC., Hefei City, Anhui (CN)

(72) Inventor: Xinman CAO, Hefei City, Anhui (CN)

(21) Appl. No.: 17/442,291

(22) PCT Filed: Jun. 22, 2021
(86) PCT No.: PCT/CN2021/101488

§ 371 Date: Sep. 23, 2021

(30) Foreign Application Priority Data
Jan. 25, 2021 (CN) 202110098156.8

(51) Int. Cl. H01L 27/108

(52) U.S. Cl. CPC H01L 27/10894; H01L 27/10897

(57) ABSTRACT

The present application provides a method for manufacturing a semiconductor structure and a semiconductor structure, relating to the field of semiconductor technology. The method for manufacturing a semiconductor structure includes: providing a substrate; forming a metal wiring layer on the substrate, a surface of the metal wiring layer having positive charges; and providing a reaction gas to the metal wiring layer.

### CROSS-REFERENCE TO RELATED APPLICATIONS

The present application is a national stage entry under 35 U.S.C. § 371 of International Application No. PCT/CN2021/101488, filed on Jun. 22, 2021, which claims the priority to Chinese Patent Application 202110098156.8, titled “METHOD FOR MANUFACTURING SEMICONDUCTOR STRUCTURE AND SEMICONDUCTOR STRUCTURE”, filed to the CNIPA on Jan. 25, 2021. The entire contents of International Application No. PCT/CN2021/101488 and Chinese Patent Application 202110098156.8 are incorporated herein by reference.

### TECHNICAL FIELD

The present application relates to the field of semiconductor technology, and in particular, to a method for manufacturing a semiconductor structure and a semiconductor structure.

### BACKGROUND

In a semiconductor manufacturing process, a semiconductor structure such as a Dynamic Random Access Memory (DRAM) is formed on a semiconductor substrate by photolithography, etching, deposition, etc. The formed DRAM usually includes a core storage region and a peripheral circuit region. The core storage region is used to dispose a plurality of storage units for storing data information. The peripheral circuit region usually includes a plurality of metal wiring layers, which are electrically connected to the storage units, so that the storage units complete the storage or reading of data information.

However, during the manufacturing of the peripheral circuit region, the conductive material in the metal wiring layers is easily corroded, which reduces the conductivity of the metal wiring layers, thereby reducing the performance of the semiconductor structure.

### SUMMARY

The embodiments of the present application provide the following technical solutions:

The first aspect of the embodiments of the present application provides a method for manufacturing a semiconductor structure, including:

providing a substrate;

forming a metal wiring layer on the substrate, a surface of the metal wiring layer having positive charges;

providing a reaction gas to the metal wiring layer, the reaction gas being used to neutralize the positive charges; and

cleaning the metal wiring layer after the positive charges are neutralized, to remove impurities remaining on the metal wiring layer.

The second aspect of the embodiments of the present application provides a semiconductor structure, including a substrate and a metal wiring layer disposed on the substrate.

The metal wiring layer is manufactured by the method for manufacturing the semiconductor structure as described above.

### BRIEF DESCRIPTION OF THE DRAWINGS

FIG. 1 is a flow diagram of a method for manufacturing a semiconductor structure according to an embodiment of the present application;

FIG. 2 is a flow diagram of forming a metal wiring layer on a substrate according to an embodiment of the present application;

FIG. 3 is a schematic structure diagram of forming a dielectric layer and a conductive layer in the method for manufacturing a semiconductor structure according to an embodiment of the present application;

FIG. 4 is a schematic structure diagram of forming a barrier layer and a transition layer in the method for manufacturing a semiconductor structure according to an embodiment of the present application;

FIG. 5 is a flow diagram of forming isolation trenches penetrating the conductive layer and extending into the dielectric layer in the method for manufacturing a semiconductor structure according to an embodiment of the present application;

FIG. 6 is a schematic structure diagram of forming a photoresist layer in the method for manufacturing a semiconductor structure according to an embodiment of the present application;

FIG. 7 is a schematic structure diagram of forming isolation trenches in the method for manufacturing a semiconductor structure according to an embodiment of the present application;

FIG. 8 is a first schematic structure diagram of forming an isolation layer in the method for manufacturing a semiconductor structure according to an embodiment of the present application;

FIG. 9 is a second schematic structure diagram of forming an isolation layer in the method for manufacturing a semiconductor structure according to an embodiment of the present application;

FIG. 10 is a schematic diagram of providing a reaction gas to the metal wiring layer in the method for manufacturing a semiconductor structure according to an embodiment of the present application;

FIG. 11 is a schematic structure diagram of neutralizing positive charges in the method for manufacturing a semiconductor structure according to an embodiment of the present application.

### REFERENCE NUMERALS

10: substrate;

20: metal wiring layer;

21: dielectric layer;

22: conductive layer;

30: barrier layer;

40: transition layer;

50: photoresist layer;

51: opening region;

60: isolation trench;

70: filling layer;

71: isolation layer.

### DETAILED DESCRIPTION

The inventor of the present application found in actual work that, during the manufacturing of a peripheral circuit of a semiconductor structure, a dielectric layer and a conductive layer that are stacked are sequentially formed on a substrate, the conductive layer is patterned through a patterning process to form a metal wiring layer, and then the surface of the metal wiring layer needs to be cleaned to remove impurities remaining on the surface of the metal wiring layer.

When the metal wiring layer is formed, the substrate is fixed in an etching device by means of electrostatic adsorption, so that the surface of the formed metal wiring layer carries positive charges. In related technologies, part of positive charges on the surface of the metal wiring layer are usually neutralized by a cleaning process, so that some positive charges still remain on the surface of the metal wiring layer. The positive charges easily react with a cleaning solution at the cleaning stage to corrode the metal wiring layer, so as to reduce the conductivity of the metal wiring layer and then reduce the performance of the semiconductor structure.

In view of the above technical problems, the embodiments of the present application provide a method for manufacturing a semiconductor structure and a semiconductor structure, a reaction gas is provided to the metal wiring layer, the reaction gas is dissociated, and the electrons generated after the dissociation neutralize the positive charges on the surface of the metal wiring layer, thereby reducing the reaction rate of a metal galvanic cell reaction, then avoiding the formation of structural defects in the metal wiring layer after cleaning the metal wiring layer with a cleaning solution, and improving the performance of the semiconductor structure.

To make the above objectives, features, and advantages of the embodiments of the present application more obvious and understandable, the following clearly and completely describes the technical solutions in the embodiments of the present application with reference to the accompanying drawings in the embodiments of the present application. Apparently, the described embodiments are some but not all of the embodiments of the present application. All other embodiments obtained by those of ordinary skill in the art without any creative efforts based on the embodiments of the present application shall fall within the protection scope of the present application.

This embodiment does not limit the semiconductor structure. The following will introduce the semiconductor structure by a Dynamic Random Access Memory (DRAM) as an example, but this embodiment is not limited to this. The semiconductor structure in this embodiment may also be other structure.

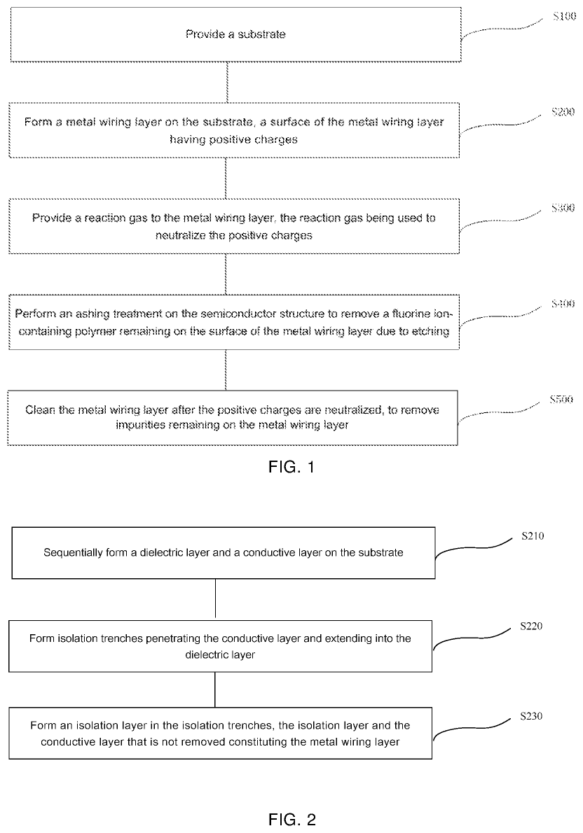

A method for manufacturing a semiconductor structure will be introduced below in conjunction with FIGS. 1 to 11.

As shown in FIG. 1, an embodiment of the present application provides a method for manufacturing a semiconductor structure, including:

S100: a substrate is provided.

The substrate is used as a support component of the semiconductor structure to support other components disposed thereon. The substrate may be made of a semiconductor material, and the semiconductor material may be one or more of silicon, germanium, a silicon-germanium compound and a silicon-carbon compound.

S200: a metal wiring layer is formed on the substrate, a surface of the metal wiring layer having positive charges. The process flow diagram is shown in FIG. 2.

Exemplarily, S210: a dielectric layer and a conductive layer are sequentially formed on the substrate.

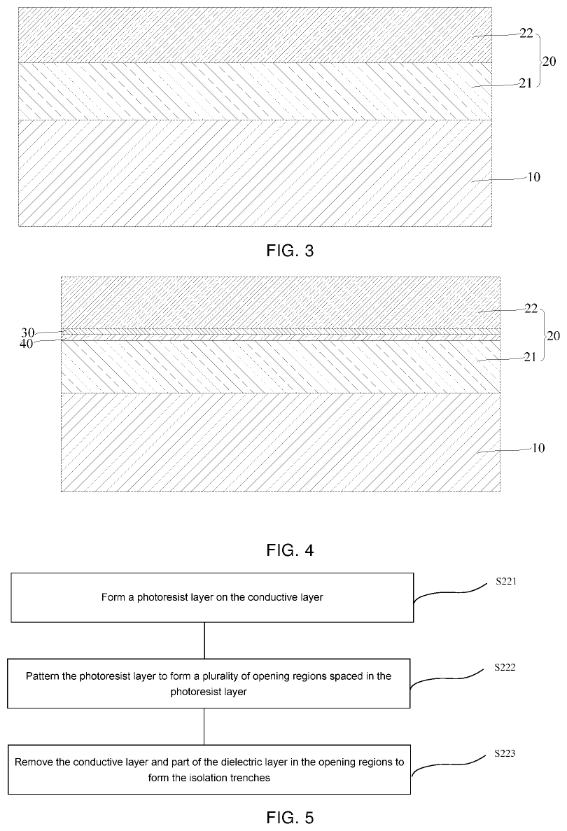

As shown in FIG. 3, a dielectric layer 21 with a certain thickness may be first formed on an upper surface of the substrate 10 by an atomic layer deposition process or a chemical vapor deposition process. The material of the dielectric layer 21 may include an insulating material such as silicon nitride to ensure insulation between the substrate 10 and the conductive layer 22.

Then, a conductive layer 22 with a certain thickness is formed on the substrate by an atomic layer deposition process or a chemical vapor deposition process. The material of the conductive layer 22 may include a conductive material such as tungsten to ensure the conductivity of the metal wiring layer.

Further, as shown in FIG. 4, in order to prevent the conductive material in the conductive layer 22 from penetrating into the dielectric layer 21, a barrier layer 30 may be formed on the dielectric layer 21. The barrier layer 30 can block the conductive material in the conductive layer 22 from penetrating into the dielectric layer 21, which ensures the conductivity of the conductive layer 22, thereby improving the yield of the semiconductor structure.

Exemplarily, the material of the barrier layer 30 may include a conductive material such as titanium nitride. While preventing the penetration between the conductive layer 22 and the dielectric layer 21, the barrier layer 30 can also realize electrical connections between the conductive layer 22 and bit line structures and between the conductive layer 22 and a peripheral circuit region.

Further, before the step of forming a barrier layer on the dielectric layer, the method further includes:

A transition layer 40 is formed on the dielectric layer 21. Specifically, a transition layer 40 with a certain thickness may be formed on the dielectric layer 21 by an atomic deposition process or a chemical vapor deposition process. The transition layer 40 is used to increase the bonding force between the dielectric layer 21 and the barrier layer 30, so as to prevent separation between the dielectric layer 21 and the barrier layer 30.

In this embodiment, the material of the transition layer 40 may include a conductive material such as titanium. While increasing the bonding force between the dielectric layer 21 and the barrier layer 30, the transition layer 40 can also realize electrical connections between the conductive layer 22 and bit line structures and between the conductive layer 22 and a peripheral circuit region.

S220: isolation trenches penetrating the conductive layer and extending into the dielectric layer are formed. The process flow diagram is shown in FIG. 5.

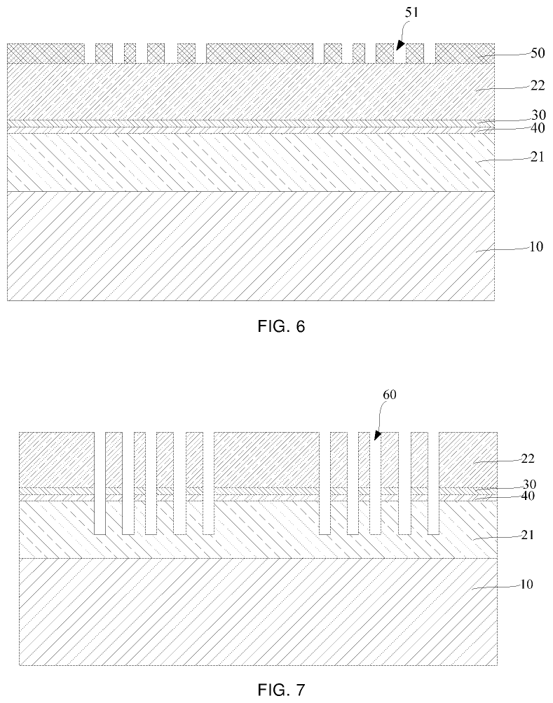

Specifically, S221: a photoresist layer is formed on the side of the conductive layer away from the substrate. The structure of the photoresist layer is shown in FIG. 6.

S222: the photoresist layer is patterned to form a plurality of opening regions spaced in the photoresist layer. That is, the photoresist layer 50 may be patterned by masking, exposure, development or etching, etc. to form a pattern on the photoresist layer 50. The pattern may include a plurality of opening regions 51 spaced, and shielding regions between the adjacent opening regions 51.

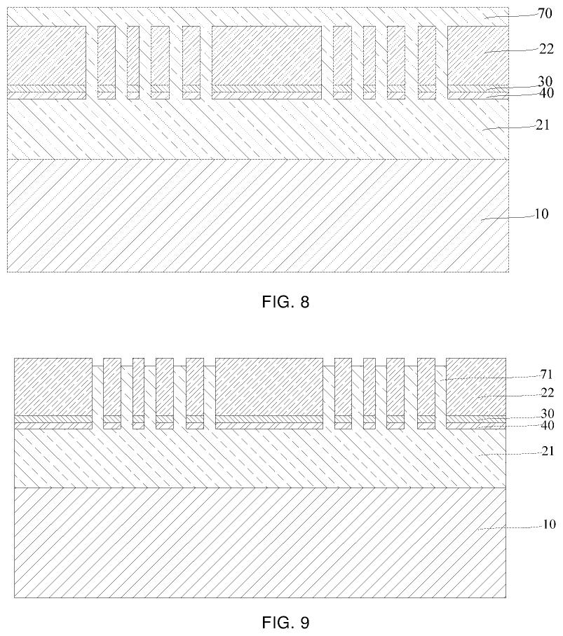

S223: the conductive layer and part of the dielectric layer in the opening regions are removed to form the isolation trenches, the structure of which is shown in FIG. 7.

That is, the conductive layer 22 and part of the dielectric layer 21 in the opening regions 51 are etched away using an etching solution or etching gas, to form isolation trenches 60 in the conductive layer 22 and the dielectric layer 21.

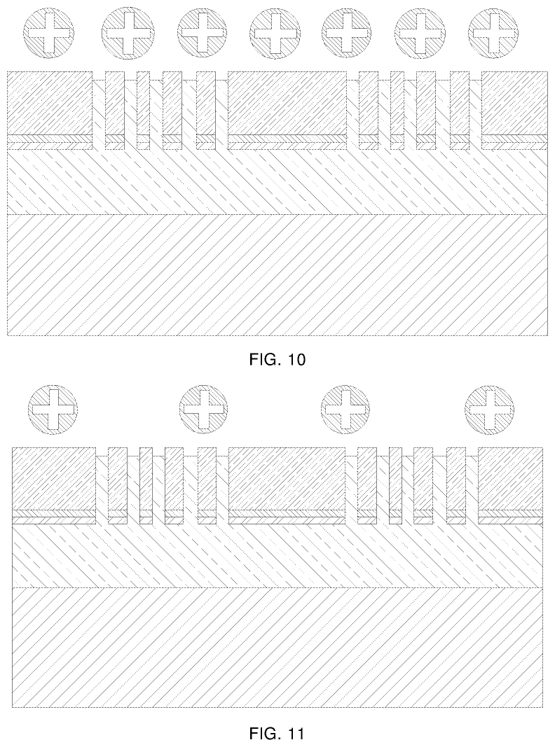

S230: an isolation layer is formed in the isolation trenches, the isolation layer and the conductive layer that is not removed constituting the metal wiring layer, the structure of which is shown in FIG. 8 and FIG. 9.

Exemplarily, as shown in FIG. 8, a filling layer 70 is formed in the isolation trenches 60 and on the surface of the conductive layer 22. Specifically, a filling layer 70 may be formed in the isolation trenches 60 by a chemical vapor deposition process, and the filling layer 70 also extends to the outside of the isolation trenches 60 and covers the surface of the conductive layer 22.

As shown in FIG. 9, the filling layer 70 on the surface of the conductive layer 22 is etched back, the filling layer 70 in the isolation trenches 60 is retained to form an isolation layer 71, and a top surface of the isolation layer 71 may be lower than a top surface of the conductive layer 22. In this embodiment, the isolation layer 71 partitions the entire conductive layer 22 into a number of conductive strips spaced, so as to select part of or all of the conductive strips to connect the bit line structures in the semiconductor structure according to the actual situation.

In this embodiment, the material of the filling layer 70 may include an insulating material such as silicon nitride, to achieve insulation of the conductive layer 22 on two sides of the isolation trenches 60.

After the step of forming a filling layer in the isolation trenches and on the surface of the conductive layer, the method for manufacturing a semiconductor structure further includes:

The photoresist layer 50 is removed. Specifically, the photoresist layer 50 on the conductive layer 22 may be removed by cleaning, to expose the conductive layer 22 and the isolation trenches 60, so as to form the isolation layer 71 in the isolation trenches 60.

S300: a reaction gas is provided to the metal wiring layer, the reaction gas being used to neutralize the positive charges. The process is shown in FIG. 10 and FIG. 11.

Specifically, since the semiconductor structure is usually manufactured in a reaction chamber of an etching device, the reaction gas can be provided into the reaction chamber of the etching device to neutralize the positive charges. The reaction gas may be oxygen or ozone. The following embodiments all take oxygen as an example for detailed description. In this step, the temperature and pressure of the reaction chamber need to be adjusted in advance to form conditions for exciting the reaction gas in the reaction chamber. For example, the temperature in the reaction chamber is 20-40° C., and the pressure in the reaction chamber is 10-30 mtorr.

After the reaction chamber satisfies the above conditions, a certain amount of oxygen is introduced into the reaction chamber as the reaction gas. Specifically, oxygen is introduced into the reaction chamber at a rate of 20-50 sccm, and the oxygen is excited under a radio frequency source with a power of 50 to 200 W to form negative oxygen ions, positive oxygen ions, free radicals and electrons.

As shown in FIG. 10, in the related technology, the metal wiring layer 20 is fixed in the reaction chamber by means of electrostatic adsorption. During the electrostatic adsorption, the tungsten on the surface of the metal wiring layer loses electrons to form positively charged tungsten ions, such as W−ne⁻=Wⁿ⁺. During subsequent cleaning of the metal wiring layer, the positive charges will react with the cleaning solution to form a galvanic cell, causing defects in the metal wiring layer.

In this embodiment, oxygen is excited to generate electrons, and the electrons neutralize the positive charges to reduce the positive charges on the surface of the metal wiring layer, as shown in FIG. 11. Because the amount of positive charges on the surface of the metal wiring layer is reduced, the reaction between the positive charges and the electrons in the cleaning solution is slowed down, which in turn reduces the reaction rate of the metal galvanic cell reaction, reduces the risk of corrosion of tungsten, and improves the conductivity of the metal wiring layer and the performance of the semiconductor structure.

In addition, the negative oxygen ions can form an oxide film with the conductive material on the surface of the metal wiring layer. Illustratively, the oxide film may be a tungsten oxide film formed by the negative oxygen ions and tungsten. The oxide film can serve as a protective film to protect the conductive layer from being damaged during subsequent cleaning, thereby ensuring the performance of the semiconductor structure.

S400: the ashing treatment is performed on semiconductor structure to remove a fluorine ion-containing polymer remaining on the surface of the metal wiring layer due to etching.

Since the process of etching the dielectric layer and the conductive layer usually uses a fluorine-containing gas as the etching gas, a fluorine ion-containing polymer is formed on the surface of the metal wiring layer 20. In order to remove the fluorine ion-containing polymer, the ashing treatment is usually performed on the semiconductor structure to remove the fluorine ion-containing polymer remaining on the surface of the metal wiring layer due to etching, thereby ensuring the subsequent cleaning effect.

In this process, the ashing treatment is carried out in the reaction chamber. Therefore, the pressure in the reaction chamber needs to be adjusted such that the reaction chamber reaches a condition for the ashing treatment. For example, the pressure in the reaction chamber is adjusted to be between 200 and 500 mtorr, which can prevent the pressure in the reaction chamber from being too low to affect the effect of the ashing treatment, and can also prevent the pressure in the reaction chamber from being too high to increase the cost for manufacturing the semiconductor structure.

Meanwhile, the temperature in the reaction chamber also needs to be adjusted such that the reaction chamber reaches a condition for the ashing treatment. For example, the temperature of the ashing treatment is 250° C.

After the reaction chamber satisfies the above conditions, a certain amount of fluorine-containing gas is introduced into the reaction chamber as the gas for ashing treatment. Specifically, the fluorine-containing gas is introduced into the reaction chamber at a rate of 500 to 3000 sccm, and the ashing treatment is performed on the semiconductor structure under a high radio-frequency power source with a power of 500 to 800 W to remove a fluoride ion-containing polymer remaining on the surface of the metal wiring layer due to etching.

In this embodiment, the fluorine-containing gas may include CF₄, CHF₃, or a mixed gas of CF₄ and CHF₃.

S500: the metal wiring layer after the positive charges are neutralized is cleaned to remove impurities remaining on the metal wiring layer.

Exemplarily, the semiconductor structure is cleaned with a cleaning solution to remove impurities remaining on the metal wiring layer, thereby ensuring the cleanliness of the metal wiring layer.

In the above process steps, the positive charges remaining on the metal wiring layer are neutralized by electrons decomposed from oxygen, which can reduce the amount of positive charges on the metal wiring layer. The metal wiring layer and the free negative charges of the cleaning solution will not form a galvanic cell, thereby reducing the corrosion to the metal wiring layer and ensuring the conductivity of the metal wiring layer.

In addition, in the above process steps, oxygen also decomposes negative oxygen ions, the negative oxygen ions can form a tungsten oxide film with tungsten on the surface of the metal wiring layer, and the tungsten oxide film can serve as a protective film to protect the conductive layer from being damaged during cleaning, thereby ensuring the performance of the semiconductor structure.

An embodiment of the present application further provides a semiconductor structure, as shown in FIG. 9, including a substrate 10 and a metal wiring layer 20 disposed on the substrate 10, wherein the metal wiring layer 20 is manufactured by the method for manufacturing a semiconductor structure according to any of the above embodiments.

In this embodiment, when the metal wiring layer is manufactured, a reaction gas is provided to the metal wiring layer, the reaction gas is dissociated, and the electrons generated after the dissociation neutralize the positive charges on the surface of the metal wiring layer, thereby reducing the reaction rate of a metal galvanic cell reaction, then avoiding the formation of structural defects after cleaning the metal wiring layer with a cleaning solution, and improving the performance of the semiconductor structure.

In addition, the reaction gas can form an oxide film with the conductive material on the surface of the metal wiring layer, and the oxide film can serve as a protective film to protect the conductive layer from being damaged during subsequent cleaning, thereby ensuring the performance of the semiconductor structure.

The embodiments or implementations in this specification are described in a progressive manner, each embodiment focuses on the differences from other embodiments, and the same or similar parts between the various embodiments may be referred to each other.

In the description of this specification, the descriptions with reference to the terms “one embodiment”, “some embodiments”, “exemplary embodiment”, “example”, “specific example”, or “some examples”, etc. mean that specific features, structures, materials or characteristics described in conjunction with the embodiments or examples are included in at least one embodiment or example of the present application.

In this specification, the schematic descriptions of the above terms do not necessarily refer to the same embodiment or example. Moreover, the described specific features, structures, materials or characteristics can be combined in an appropriate manner in any one or more embodiments or examples.

Finally, it should be noted that the above embodiments are merely intended to describe, but not to limit, the technical solutions of the present application. Although the present application is described in detail with reference to the above embodiments, those of ordinary skill in the art should understand that various modifications may be made to the technical solutions described in the foregoing embodiments or equivalent substitutions may be made to some or all technical features thereof, and these modifications or substitutions do not make the essences of the corresponding technical solutions depart from the scope of the technical solutions of the embodiments of the present application.

1. A method for manufacturing a semiconductor structure, comprising:
providing a substrate;
forming a metal wiring layer on the substrate, a surface of the metal wiring layer having positive charges;
providing a reaction gas to the metal wiring layer, the reaction gas being used to neutralize the positive charges; and
cleaning the metal wiring layer after the positive charges are neutralized, to remove impurities remaining on the metal wiring layer.

2. The method for manufacturing the semiconductor structure according to claim 1, wherein the providing a reaction gas to the metal wiring layer, the reaction gas being used to neutralize the positive charges comprises:
providing oxygen as the reaction gas; and
exciting the oxygen to form negative oxygen ions, positive oxygen ions, free radicals and electrons, the electrons neutralizing the positive charges, and the negative oxygen ions and a conductive material on the surface of the metal wiring layer forming an oxide film.

3. The method for manufacturing the semiconductor structure according to claim 2, wherein the forming a metal wiring layer on the substrate comprises:
sequentially forming a dielectric layer and a conductive layer on the substrate;
forming isolation trenches penetrating the conductive layer and extending into the dielectric layer; and
forming an isolation layer in the isolation trenches, the isolation layer and the conductive layer that is not removed constituting the metal wiring layer.

4. The method for manufacturing the semiconductor structure according to claim 3, wherein the forming isolation trenches penetrating the conductive layer and extending into the dielectric layer comprises:
forming a photoresist layer on the conductive layer;
patterning the photoresist layer to form a plurality of opening regions spaced in the photoresist layer; and
removing the conductive layer and part of the dielectric layer in the opening regions to form the isolation trenches.

5. The method for manufacturing the semiconductor structure according to claim 4, wherein the forming an isolation layer in the isolation trenches comprises:
forming a filling layer in the isolation trenches and on a surface of the conductive layer; and
removing the filling layer on the surface of the conductive layer to form the isolation layer.

6. The method for manufacturing the semiconductor structure according to claim 5, wherein before the removing the conductive layer and part of the dielectric layer in the opening regions, and after the forming a filling layer in the isolation trenches and on a surface of the conductive layer, the method further comprises:
removing the photoresist layer to expose the conductive layer and the isolation trenches.

7. The method for manufacturing the semiconductor structure according to claim 6, wherein the sequentially forming a dielectric layer and a conductive layer on the substrate comprises:
forming a barrier layer on the dielectric layer, the barrier layer being used to block the conductive material in the conductive layer from penetrating into the dielectric layer.

8. The method for manufacturing the semiconductor structure according to claim 7, wherein a material of the barrier layer comprises titanium nitride.

9. The method for manufacturing the semiconductor structure according to claim 8, wherein before the forming a barrier layer on the dielectric layer, the method further comprises:
forming a transition layer on the dielectric layer, the transition layer being used to increase a bonding force between the dielectric layer and the barrier layer.

10. The method for manufacturing the semiconductor structure according to claim 9, wherein a material of the transition layer comprises titanium.

11. The method for manufacturing the semiconductor structure according to claim 1, wherein the cleaning the metal wiring layer after the positive charges are neutralized, to remove impurities remaining on the metal wiring layer, comprises:
cleaning the semiconductor structure with a cleaning solution to remove the impurities remaining on the metal wiring layer.

12. The method for manufacturing the semiconductor structure according to claim 11, wherein before the cleaning the semiconductor structure with a cleaning solution, and after the providing a reaction gas to the metal wiring layer, the method further comprises:
performing an ashing treatment on the semiconductor structure to remove a fluorine ion-containing polymer remaining on the surface of the metal wiring layer due to etching.

13. The method for manufacturing the semiconductor structure according to claim 12, wherein the ashing treatment is carried out at a temperature of 250° C. and under a high radio-frequency power source with a power of 500 to 800 W.

14. The method for manufacturing the semiconductor structure according to claim 12, wherein gas used in the ashing treatment is a fluorine-containing gas, a flow rate of the fluorine-containing gas is 500 to 3000 sccm, the ashing treatment is carried out in a reaction chamber, and a pressure of the reaction chamber is 200 to 500 mtorr.

15. The method for manufacturing the semiconductor structure according to claim 3, wherein a material of the conductive layer comprises tungsten.

16. A semiconductor structure, comprising a substrate and a metal wiring layer disposed on the substrate;
wherein the metal wiring layer is manufactured by the method for manufacturing the semiconductor structure according to claim 1.
